(19) United States
(12) Patent Application Publication
(10) Pub. No.: US 2016/0184890 A1
(43) Pub. Date: Jun. 30, 2016

(54) CHROMIDE COATINGS, ARTICLES COATED WITH CHROMIDE COATINGS, AND PROCESSES FOR FORMING CHROMIDE COATINGS

(71) Applicants: Lawrence Bernard KOOL, Clifton Park, NY (US); Bhupendra Kumar GUPTA, Cincinnati, OH (US); Mark ROSENZWEIG, West Chester, OH (US); Samar Jyoti KALITA, Cincinnati, OH (US)

(72) Inventors: Lawrence Bernard KOOL, Clifton Park, NY (US); Bhupendra Kumar GUPTA, Cincinnati, OH (US); Mark ROSENZWEIG, West Chester, OH (US); Samar Jyoti KALITA, Cincinnati, OH (US)

(73) Assignee: GENERAL ELECTRIC COMPANY, Schenectady, NY (US)

(21) Appl. No.: 14/585,890

(22) Filed: Dec. 30, 2014

(51) Int. Cl. B22F 1/00; C23C 16/56; C23C 16/44

(52) U.S. Cl. CPC B22F 1/007; C23C 16/44; C23C 16/56

(57) ABSTRACT

A slurry coating composition for enriching a surface region of a metal-based substrate with chromium includes a metallic powder including chromium powder in the Cr(0) oxidation state and aluminum powder; a binder including colloidal silica to bind the metallic powder; and a stabilizer, wherein the chromium powder comprises at least about 80% by weight of the metallic powder and the aluminum powder comprises up to about 10% by weight of the metallic powder. A process of forming a coating and enriching a surface region of a component formed of a nickel-based superalloy with chromium includes applying the slurry coating composition to the surface region of the component to form a slurry coating on the surface region; curing the slurry coating to form a green coating; and sintering the green coating to form a coating having chromium in the alpha phase at an operating temperature of the component between about 1200° C. to about 1800° C. A nickel-based superalloy component of a gas turbine engine has a coating and surface region enriched with chromium formed by the process.

### BACKGROUND

The present technology generally relates to protective coating systems suitable for components exposed to high temperatures, such as the hostile thermal environment of a gas turbine engine. More particularly, the present technology relates to slurry coating compositions and processes for selectively enriching surface regions of a component, for example, the under-platform regions on a turbine blade, with corrosion-resistant metals such as chromium.

Components of turbine engines, such as the blades and vanes (nozzles) within the turbine section of a gas turbine engine, are often formed of an iron, nickel, or cobalt-base superalloy. A turbine blade has an airfoil against which hot combustion gases are directed during operation of the gas turbine engine, and whose surface is therefore subjected to severe attack by oxidation, corrosion and erosion. The blade further includes a platform and an under-platform or root section separated from the airfoil by the platform that, while not directly exposed to hot gas path, are still exposed to high temperatures and are susceptible to oxidation and corrosion. Turbine blades or buckets are typically anchored to the perimeter of a rotor or wheel by forming the rotor to have slots with dovetail cross-sections that interlock with a complementary dovetail profile on the root section of each blade.

Due to the severity of their operating environments, turbine blades often require environmentally protective coatings on the surfaces of their airfoils and platforms exposed to the hot gas path. Diffusion coatings such as chromide, aluminide, and platinum aluminide coatings are widely used as environmental coatings in gas turbine engine applications because of their oxidation resistance. Such coatings, which are typically applied to the internal and external surfaces of a blade, are produced by a thermal/chemical reaction process that results in the near-surface region of the substrate being enriched with, depending on the type of coating, chromium, aluminum, platinum, etc., as well as intermetallics that form as a result of reactions between the deposited corrosion-resistant specie(s) and the substrate material. Diffusion coating processes typically take place in a reduced and/or inert atmosphere at elevated temperatures. Common processes include pack cementation and noncontact vapor (gas phase) deposition techniques, or by diffusing corrosion-resistant species deposited by chemical vapor deposition (CVD) or slurry coating.

In pack cementation and noncontact vapor deposition techniques, vapor of the desired corrosion-resistant coating species (e.g., chromium, aluminum, etc.) is generated and caused to contact surfaces on which the coating is desired. The vapor reacts with the surface to deposit the desired coating specie(s), which are then diffused into the surface through a heat treatment. Aluminide diffusion coatings deposited by pack cementation or noncontact vapor deposition are often preferred for turbine blade airfoils. The dovetails of turbine blades are typically machined prior to the diffusion coating process, and may be masked during coating so that the dovetail will properly assemble with the dovetail slot in the rotor during engine build. However, during engine operation the under-platform regions of the blade can become corroded. In the past, corrosion of under-platform regions of turbine blades has been addressed by applying a vapor-phase chromide coating. While capable of improving corrosion resistance, vapor-phase chromizing processes require masking to prevent the chromide coating from being deposited on other surfaces of the blade, such as those already provided with an aluminide coating. However, masking is time-consuming, expensive, and not always effective.

Slurry processes generally entail the use of an aqueous or organic solvent slurry containing a volatile liquid vehicle and a powder of the corrosion-resistant coating specie(s) that can be sprayed or otherwise applied to a substrate, after which the substrate is heated to evaporate the volatile components of the slurry and, with further heating, diffuse the remaining coating species into the substrate. An example of a slurry composition is disclosed in U.S. Pat. No. 3,248,251 as containing aluminum particulates dispersed in an aqueous, acidic bonding solution that also contains metal chromate, dichromate or molybdate, and phosphate (the latter of which serves as a binder). The chromate ions are known to improve corrosion resistance. One prevalent theory described in U.S. Pat. No. 6,074,464 is that chromate ions passivate the bonding solution toward aluminum and inhibit the oxidation of metallic aluminum. In this manner, particulate aluminum can be combined with the bonding solution without undesirable reactions between the solution and aluminum.

A drawback of slurry compositions of the type taught by the prior art discussed above is the reliance on the presence of chromates, which are considered toxic. In particular, hexavalent chromium is considered to be a carcinogen. When compositions containing this form of chromium are used (e.g., in spray booths), special handling procedures that must be closely followed to satisfy health and safety regulations can result in increased costs and decreased productivity. Therefore, attempts have been made to formulate slurry compositions which do not rely on the presence of chromates. For example, U.S. Pat. No. 6,150,033 describes chromate-free coating compositions used to protect metal substrates such as stainless steel. Many of the compositions disclosed in this patent are based on an aqueous phosphoric acid bonding solution, which comprises a source of magnesium, zinc, and borate ions. However, chromate-free slurry compositions can have various disadvantages, such as instability over the course of several hours (or even minutes), and generation of unsuitable levels of gases such as hydrogen. Furthermore, chromate-free slurry compositions have been known to thicken or partially solidify, rendering them very difficult to apply to a substrate by spray techniques. Moreover, the use of phosphoric acid in the compositions may also contribute to instability, especially if chromate compounds are not present since the latter apparently passivates the surfaces of the aluminum particles. In the absence of chromates, phosphoric acid may attack the metallic aluminum particles in the slurry composition, rendering the composition thermally and physically unstable. At best, such a slurry composition will be difficult to store and apply to a substrate.

In view of the above, there are ongoing efforts to develop new slurry compositions capable of forming environmentally-protective coatings on substrates. Such compositions should be capable of incorporating as much corrosion-resistant species as necessary into a substrate, and should also be substantially free of chromate compounds, especially hexavalent chromium. Moreover, improved slurry compositions should be chemically and physically stable for extended periods of use and storage, amenable to slurry application by various techniques such as spraying, painting, and the like, and should be generally compatible with other techniques which might be used to treat a particular metal substrate, for example, superalloy components such as turbine blades.

### SUMMARY

In accordance with an example of the technology disclosed herein, a slurry coating composition for enriching a surface region of a metal-based substrate with chromium comprises a metallic powder including chromium powder in the Cr(0) oxidation state and aluminum powder; a binder including colloidal silica to bind the metallic powder; and a stabilizer, wherein the chromium powder comprises at least about 80% by weight of the metallic powder and the aluminum powder comprises up to about 10% by weight of the metallic powder.

In accordance with an example of the technology disclosed herein, a method of forming a coating and enriching a surface region of a component formed of a nickel-based superalloy with chromium comprises applying the slurry coating composition to the surface region of the component to form a slurry coating on the surface region; curing the slurry coating to form a green coating; and sintering the green coating to form a coating having chromium in the alpha phase at an operating temperature of the component between about 1200° C. to about 1800° C.

In accordance with an example of the technology disclosed herein, a nickel-based superalloy component of a gas turbine engine has a coating and surface region enriched with chromium formed by the process.

### BRIEF DESCRIPTION OF THE DRAWINGS

These and other features, aspects, and advantages of the present technology will become better understood when the following detailed description is read with reference to the accompanying drawings in which like characters represent like parts throughout the drawings, wherein:

FIG. 1 schematically depicts a turbine component that may be coated according to the present technology;

FIG. 2 depicts a coating according to an example of the present technology;

FIG. 3 depicts a coating according to an example of the present technology;

FIG. 4 depicts a coating according to an example of the present technology;

FIG. 5 depicts a coating according to an example of the present technology; and

FIG. 6 depicts a phase diagram of a Ni—Cr alloy.

### DETAILED DESCRIPTION

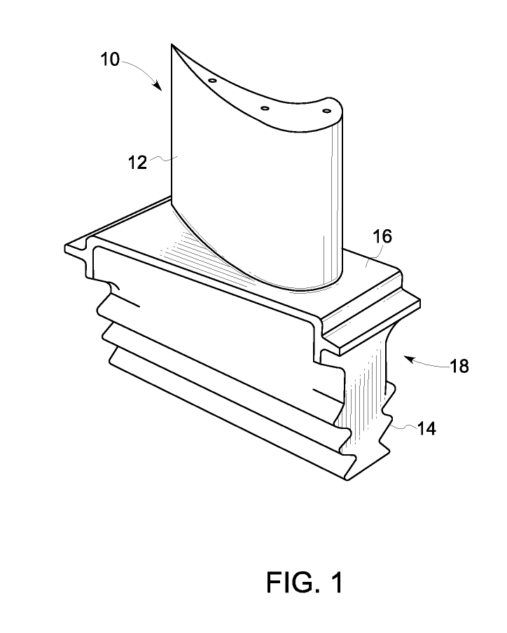

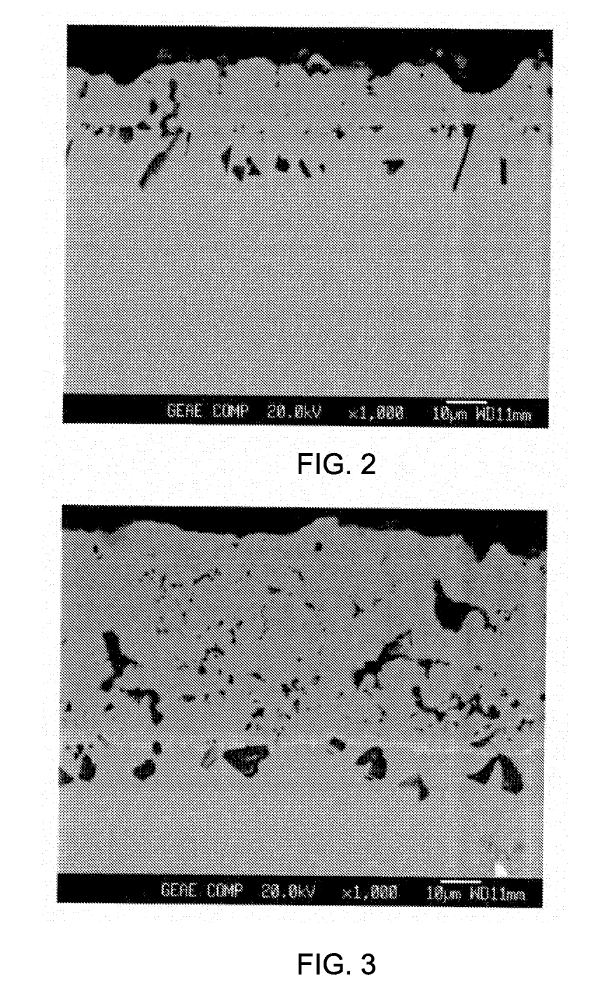

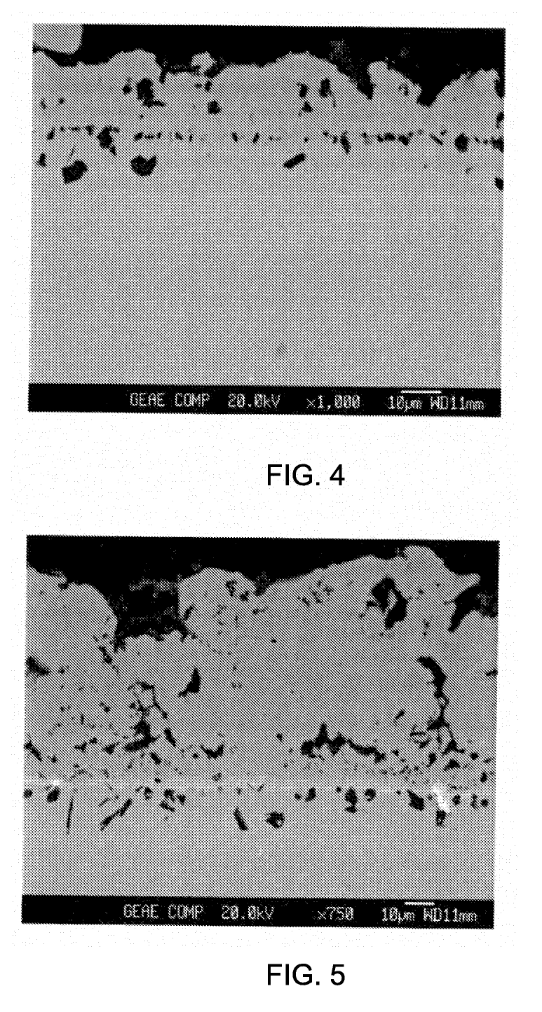

The slurry coating compositions and process of the present technology may be used to selectively enrich surface regions of substrates with chromium, and also aluminum if desired. One application may be the under-platform regions on turbine blades of gas turbine engines. Referring to FIG. 1, a high pressure turbine blade 10 includes an airfoil 12 against which hot combustion gases are directed during operation of the gas turbine engine, and whose surface is therefore subjected to severe attack by oxidation, corrosion, (e.g. hot sulfate corrosion), and erosion. The blade 10 is anchored to a turbine disk (not shown) with a dovetail 14 formed on a root section of the blade 10. A platform 16 separates the airfoil 12 and the dovetail 14, and the root section, its dovetail 14, and the underside of the platform 16 are referred to as under-platform regions 18 of the blade 10. Though not directly exposed to the hot gas path of a turbine engine, the under-platform regions 18 are nonetheless susceptible to oxidation and corrosion that may be induced by sulfur containing dirt, debris, and/or deposits entrained in the cooling air that flows around the under-platform region of the blade. Slurry coating compositions and processes of the present technology may be used to selectively form a chromium-containing coating on the surfaces of the under-platform regions 18 of the blade 10 of FIG. 1, as well as surfaces of other components similarly subjected to oxidation and corrosion. Examples of the coatings that may be applied by the present technology are shown in FIGS. 2-5.

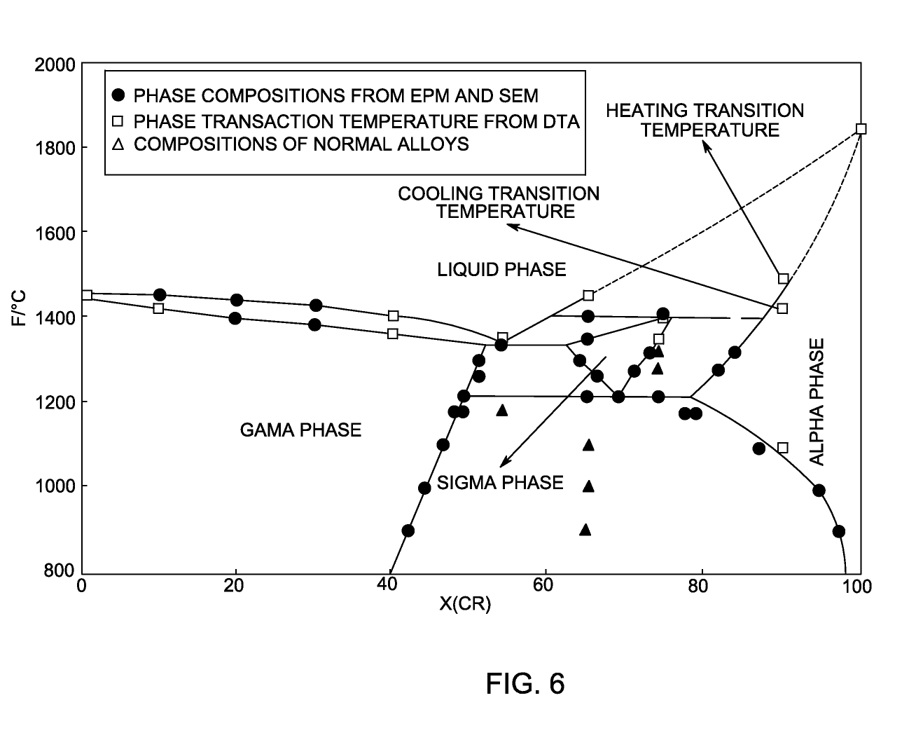

Referring to FIG. 6, a Ni—Cr phase diagram shows that at temperatures from about 1200° C. (approximately 2200° F.) to about 1800° C. (approximately 3270° F.), the alpha phase of chromium exists from about 78-100 at. %. In order to obtain an alpha phase chromium coating applied to a nickel based superalloy gas turbine component, e.g. a turbine blade, at operating temperatures of the component, the at. % of the chromium in the coating should be at least 78%. Given the similar atomic masses of Cr and Ni, the metallic powder of the slurry coating composition may be about 80-100% by weight Cr. The slurry coating composition may include Cr powder in the Cr(0) oxidation state, i.e. hexavalent free, and is therefore not restricted as is Cr(VI), i.e. hexavalent chromium. The slurry powder particle size distribution may be from about 1 to 5 μm.

The composition of the chromium-based powder and its amount in the slurry composition may depend on the amount of chromium desired for the under-platform regions 18. In general, suitable amounts of chromium and optionally aluminum in the slurry composition should exceed their respective amounts in the substrate to be protected. The chromium content of the slurry composition should be sufficient to compensate for any projected loss of chromium from the under-platform regions 18 under expected operating conditions, such as temperatures, temperature/time schedules and cycles, and environmental conditions.

In addition to Cr, the metallic powder of the slurry coating composition may include aluminum to provide uniformity and enhance diffusion of the coating. The Al powder particle size distribution may be from about 10-14 μm and may be up to about 10%, for example about 1-5%, by weight of the metallic powder. Other metals may be included to provide enhanced oxidation resistance, phase stability, environmental resistance, and sulfidation resistance. Metals that may be included in the powder of the slurry coating composition include Co, Fe, Ti, Ta, W, Re, Mo, Hf, Si, and Pt. The powder may also contain various other elements and other materials at impurity levels, e.g., less than about 1% by weight.

The metallic powder may constitute, by weight, about 25% to about 80%, more preferably about 30% to about 50%, of the entire slurry composition. The powder particles may be in the form of spherical particles, though other forms are possible as well, such as wire, wire mesh, and those described above for the colloidal silica. The metallic powder can be used in a variety of standard sizes. Acceptable sizes for the powder particles will depend on several factors, such as the alloy of the under-platform regions 18, the technique by which the slurry is to be applied to the under-platform regions 18, and the presence and amounts of other potential constituents in the slurry.

The slurry coating compositions of the present technology may include a binder, for example, a non-organic binder. One binder that may be used is colloidal silica. The term “colloidal silica” is meant to embrace any dispersion of fine particles of silica in a medium of water or another solvent, with water being preferred such that the slurry composition is a water-based (aqueous) system. Dispersions of colloidal silica are available from various chemical manufacturers in either acidic or basic form. Moreover, various shapes of silica particles can be used, e.g., spherical, hollow, porous, rod, plate, flake, or fibrous, as well as amorphous silica powder. The particles may have an average particle size in a range of about 10 nanometers to about 100 nanometers. Commercial examples of colloidal silica are available under the names Ludox® from Sigma-Aldrich Co. LLC and Remasol® from REMET Corporation, of Utica, N.Y., USA.

The amount of colloidal silica present in the composition will depend on various factors, for example, the amount of metallic powder used and the presence (and amount) of any other constituents in the slurry, for example, an organic stabilizer as discussed below. Colloidal silica appears to function primarily as a very effective binder in the slurry composition. Processing conditions are also a consideration, for example, how the slurry is formed and applied to the under-platform regions 18. The colloidal silica may be present at a level in the range of about 1% to about 25% by weight, based on silica solids as a percentage of the entire composition. In especially preferred embodiments, the amount is in the range of about 10% to about 20% by weight.

In addition to the metallic powder and colloidal silica, the slurry compositions may further include other constituents, for example wetting agents and metal powder stabilizers. One example of a wetting agent and stabilizer is glycerol, C₃H₅(OH)₃, sometimes referred to as “glycerin” or “glycerine.” Glycerol can readily be obtained from fats, i.e., glycerides. It is believed that glycerol is especially effective at passivating aluminum within the slurry.

Suitable amounts for the stabilizer in the slurry composition are believed to be in a range of about 0.1% by weight to about 20% by weight, for example about 0.5% to about 15% by weight, based on the total weight of the slurry composition. The amount of stabilizer will depend on various factors including the specific type of stabilizer used, its water-miscibility, the effect of the stabilizer on the viscosity of the slurry composition, the amount of metallic powder in the slurry composition, the particle sizes of the metallic powder, the surface-to-volume ratio of the powder particles, the specific technique used to prepare the slurry, and the presence of any other components in the slurry composition. For example, if used in sufficient quantities, the stabilizer might be capable of preventing or minimizing any undesirable reaction between the metallic powder and any phosphoric acid present in the slurry. The organic stabilizer may be present in an amount sufficient to chemically stabilize the metallic powder during contact with water or any other aqueous components of the slurry, meaning that slurry remains substantially free of undesirable chemical reactions, including those that would increase the viscosity and/or temperature of the composition to unacceptable levels. For example, unacceptable increases in temperature or viscosity are those which could prevent the slurry composition from being easily applied to the under-platform regions 18, e.g., by spraying. As a very general guideline, compositions deemed to be unstable are those that exhibit (e.g., after a short induction period) a temperature increase of greater than about 10° C. within about one minute, or greater than about 30° C. within about ten minutes. In the alternative (or in conjunction with a temperature increase), these compositions may also exhibit unacceptable increases in viscosity over a similar time period.

The slurry compositions may also contain various other ingredients as well, including compounds known to those involved in slurry preparations. Examples include thickening agents, dispersants, deflocculants, anti-settling agents, anti-foaming agents, plasticizers, emollients, surfactants, and lubricants. In general, such additives may be used at a level in the range of about 0.01% by weight to about 10% by weight, based on the weight of the entire slurry composition.

As mentioned above, the slurry composition may be aqueous. In other words, it includes a liquid carrier (e.g., the medium in which the colloidal silica is employed) that is primarily or entirely water. As used herein, “aqueous” refers to slurry compositions in which at least about 65% and preferably at least about 80% of the volatile components are water. Thus, a limited amount of other liquids may be used in admixture with the water. Examples of the other liquids or “carriers” include alcohols, for example, lower alcohols with 1-4 carbon atoms in the main chain, such as ethanol. Halogenated hydrocarbon solvents are another example. Selection of a particular carrier composition will depend on various factors, such as the evaporation rate required during treatment of the under-platform regions 18 with the slurry, the effect of the carrier on the adhesion of the slurry to the under-platform regions 18, the solubility of additives and other components in the carrier, the “dispersability” of powders in the carrier, the carrier's ability to wet the under-platform regions 18 and modify the rheology of the slurry composition, as well as handling requirements, cost requirements, and environmental/safety concerns.

A suitable amount of liquid carrier employed is usually the minimum amount sufficient to keep the solid components of the slurry in suspension. Amounts greater than that level may be used to adjust the viscosity of the slurry composition, depending on the technique used to apply the composition. In general, the liquid carrier will typically constitute about 10% by weight to about 30% by weight, for example about 20% by weight, of the entire slurry composition. It should be noted that the slurry is termed a solid-in-liquid emulsion.

The use of this slurry composition is especially advantageous for enhancing the chromium content (and optionally the aluminum content) of the under-platform regions 18 turbine blades 10 formed of superalloy materials, though its application to other metal substrates is also within the scope of the invention. The term “superalloy” is usually intended to embrace complex cobalt, nickel, and iron-based alloys that include one or more other elements, such as chromium, rhenium, aluminum, tungsten, molybdenum, titanium, etc. Superalloys are described in many references, including U.S. Pat. No. 5,399,313, which is incorporated herein by reference. The actual configuration of blades treated with the slurry composition of this invention may vary widely, and therefore can differ from that shown in FIG. 1.

The slurry coatings can be applied to the under-platform regions 18 by a variety of techniques known in the art. Some examples of the deposition techniques slip-casting, brush-painting, dipping, spraying, pouring, rolling, or spin-coating onto the surfaces of the under-platform regions 18. Spray-coating is one way to apply the slurry coating to under-platform regions 18 of the turbine blade 10. The viscosity of the coating can be readily adjusted for spraying by varying the amount of liquid carrier used.

The slurry can be applied as one layer or multiple layers. Multiple layers may sometimes be required to deliver the desired amount of chromium metal to the under-platform regions 18. If a series of layers is used, a heat treatment may be performed after each layer is deposited to accelerate removal of the volatile components. After the full thickness of the slurry has been applied, the slurry coating may be allowed to “air dry” before further processing to form the final coating. Alternatively and/or additionally, a heat treatment may be carried out to further remove volatile materials, such as the organic solvents and water. An exemplary heating regimen is about five minutes to about two hours at a temperature in the range of about 80° C. to about 200° C. (about 176° F. to about 392° F.). Longer heating times can compensate for lower heating temperatures, and vice versa.

The uniformly applied slurry coating may also be “cured” to provide a green coating. For example, the component or article (e.g. turbine blade) with the applied slurry coating may be heated to about 150° C. for one hour. Such treatment may be sufficient to remove volatiles, e.g. water and glycerol, from the slurry coating.

The green coating may then be heated to a temperature sufficient to sinter the slurry coating and diffuse the chromium (and, if present, aluminum and/or other metallic species) into the near-surface regions of the under-platform regions 18 and to sinter the green coating into a final coating. As used herein, a “near-surface region” extends to a depth of up to about 200 μm into the surface of the under-platform regions 18, typically a depth of about 75 μm and preferably at least 25 μm into the surface, and includes both a chromium-enriched region closest to the surface and an area of interdiffusion immediately below the enriched region. Temperatures required for this chromizing step (i.e., the diffusion temperature) will depend on various factors, including the composition of the under-platform regions 18, the specific composition and thickness of the slurry, and the desired depth of enhanced chromium concentration. Usually the diffusion temperature is within the range of about 650° C. to about 1100° C. (about 1200° F. to about 2010° F.), for example about 800° C. to about 950° C. (about 1472° F. to about 1742° F.). These temperatures are also high enough to completely remove (by vaporization or pyrolysis) any organic compounds present, including stabilizers such as glycerol. The diffusion heat treatment can be carried out by any convenient technique, including heating in a vacuum or inert gas within an oven.

The time required for the diffusion heat treatment will depend on the factors described above. Generally, the time will range from about thirty minutes to about eight hours. In some instances, a graduated heat treatment is desirable. As a very general example, the temperature could be raised to about 650° C., held there for a period of time, and then increased in steps to about 850° C. Alternatively, the temperature could initially be raised to a threshold temperature such as 650° C. and then raised continuously, e.g., about 1° C. per minute, to reach a temperature of about 850° C. in about 200 minutes.

Alternatively, the green coating may be subjected to a pack CVD vapor phase chromide process to form the final coating. Process parameters of temperature, gas flow rate, and chromium chloride concentration may be selected to control the deposition rate. The transformation of the green coating to the final coating by the pack CVD process allows for the use of less aluminum and provides a reduction in the porosity of the final coating. A thicker coating, for example a coating having a thickness of up to about 1.75 mil (about 45 nm), may be produced by the pack CVD process. The pack CVD process is also less sensitive to the slurry powder particle size distribution because of the reduced porosity of the coating. The coating also has a metallurgical bond with the substrate of the component or article because it is a diffusion bond. The coating also provides an alpha chromium structure which is highly corrosion resistant.

It is to be understood that not necessarily all such objects or advantages described above may be achieved in accordance with any particular example. Thus, the systems and techniques described herein may be embodied or carried out in a manner that achieves or optimizes one advantage or group of advantages as taught herein without necessarily achieving other objects or advantages as may be taught or suggested herein.

While only certain features of the present technology have been illustrated and described herein, many modifications and changes will occur to those skilled in the art. It is, therefore, to be understood that the appended claims are intended to cover all such modifications and changes.

What is claimed is:

1. A slurry coating composition for enriching a surface region of a metal-based substrate with chromium, the slurry coating composition comprising:
a metallic powder including chromium powder in the Cr(0) oxidation state and aluminum powder;
a binder including colloidal silica to bind the metallic powder; and
a stabilizer, wherein the chromium powder comprises at least about 80% by weight of the metallic powder and the aluminum powder comprises up to about 10% by weight of the metallic powder.

2. The slurry coating composition according to claim 1, wherein a particle size distribution of the chromium powder is about 1 to 5 μm.

3. The slurry coating composition according to claim 1, wherein a particle size distribution of the aluminum powder is about 10 to 14 μm.

4. The slurry coating composition according to claim 1, wherein the metallic powder is present in the slurry coating composition at a range of about 25% by weight to about 80% by weight of the slurry coating composition.

5. The slurry coating composition according to claim 1, wherein the colloidal silica comprises a liquid carrier selected from the group consisting of: water, alcohols, halogenated hydrocarbon solvents, and compatible mixtures thereof.

6. The slurry coating composition according to claim 1, wherein the colloidal silica is present in the slurry coating composition at a range of about 1% by weight to about 25% by weight, based on silica solids as a percentage of the slurry coating composition.

7. The slurry coating composition according to claim 1, wherein the silica in the colloidal silica has an average particle size in the range of about 10 nanometers to about 100 nanometers.

8. The slurry coating composition according to claim 1, wherein the stabilizer is present at a range of about 0.1% by weight to about 20% by weight.

9. A process of forming a coating and enriching a surface region of a component formed of a nickel-based superalloy with chromium, the process comprising:
applying the slurry coating composition according to claim 1 to the surface region of the component to form a slurry coating on the surface region;
curing the slurry coating to form a green coating; and
sintering the green coating to form a coating having chromium in the alpha phase at an operating temperature of the component between about 1200° C. to about 1800° C.

10. The process according to claim 9, wherein curing the slurry coating comprises heating the coated component at about 150° C. for about one hour.

11. The process according to claim 9, wherein sintering the green coating comprises subjecting the coated component to a pack CVD vapor phase chromide process.

11. The process according to claim 9, wherein sintering the green coating diffuses the metallic chromium into the surface region at a depth of between about 25 μm to about 200 micrometers.

12. The process according to claim 9, wherein sintering comprises heating the coated component to between about 650° C. to about 1100° C.

13. A nickel-based superalloy component of a gas turbine engine having a coating and surface region enriched with chromium formed by the process of claim 9.

14. The component according to claim 13, wherein the coating is at least about 45 μm thick.

15. A slurry coating composition for enriching a surface region of a metal-based substrate with chromium, the slurry coating composition comprising:
a metallic powder including chromium powder in the Cr(0) oxidation state powder;
a binder including colloidal silica to bind the metallic powder; and
a stabilizer.

16. A process of forming a coating and enriching a surface region of a component formed of a nickel-based superalloy with chromium, the process comprising:
applying the slurry coating composition according to claim 15 to the surface region of the component to form a slurry coating on the surface region;
curing the slurry coating to form a green coating; and
sintering the green coating to form a coating having chromium in the alpha phase at an operating temperature of the component between about 1200° C. to about 1800° C.

17. A slurry coating composition for enriching a surface region of a metal-based substrate with chromium, the slurry coating composition consisting of:
a metallic powder including chromium powder in the Cr(0) oxidation state;
a binder including colloidal silica to bind the metallic powder; and
a stabilizer.

18. A process of forming a coating and enriching a surface region of a component formed of a nickel-based superalloy with chromium, the process comprising:
applying the slurry coating composition according to claim 17 to the surface region of the component to form a slurry coating on the surface region;
curing the slurry coating to form a green coating; and
sintering the green coating to form a coating having chromium in the alpha phase at an operating temperature of the component between about 1200° C. to about 1800° C.
